(19) United States
(12) Patent Application Publication
(10) Pub. No.: US 2023/0080422 A1
(43) Pub. Date: Mar. 16, 2023

(54) DISPLAY PANEL WITH NARROW LOWER BORDER AND ELECTRONIC DEVICE

(71) Applicant: ZHE JIANG CHANGXING HELI OPTOELECTRONIC TECHNOLOGY CO .,LTD, Huzhou (CN)

(72) Inventors: Bin XIAO, Huzhou (CN); Guohua LIU, Huzhou (CN)

(73) Assignee: ZHE JIANG CHANGXING HELI OPTOELECTRONIC TECHNOLOGY CO .,LTD, Huzhou (CN)

(21) Appl. No.: 17/041,443

(22) PCT Filed: Aug. 19, 2019
(86) PCT No.: PCT/CN2019/101459

§ 371 Date: Sep. 25, 2020

(51) Int. Cl. G02F 1/1345; G02F 1/1362; G06F 3/041

(52) U.S. Cl. CPC G02F 1/13452; G02F 1/13629; G06F 3/04164

(57) ABSTRACT

A display panel and an electronic device with a narrow lower border. The display panel includes a left border, a right border and a lower border. The lower border has a length direction extending from the left border to the right border. The lower border is provided with a first detection area, a first installation area, a bonding area, a second installation area and a second detection area which are arranged sequentially along the length direction. The bonding area is used to bond a flexible circuit board. The first installation area is used to install a first driving chip. The second installation area is used to install a second driving chip. The first detection area and the second detection area are used to transmit test signals to the display panel before bonding the flexible circuit board and before installing the first driving chip and the second driving chip.

### TECHNICAL FIELD

The present invention relates to the technical field of display technology, and in particular to a display panel with a narrow lower border and an electronic device with the display panel.

### BACKGROUND ART

With the increasing trend of full screen display device, the technology of narrowing the border of a display panel has been paid more and more attention. Compared with the left and right borders, the upper and lower borders become the key and difficult points of narrow border technology. Among them, the lower border of the display panel needs to place the source driving circuit, the timing control circuit, the touch control circuit, the detection circuit, etc., and usually needs to be bonding with a flexible printed circuit (FPC) board, so it is difficult to further narrow the lower border of the display panel due to factors such as IC architecture, manufacturing process, etc.

### TECHNICAL PROBLEM

FIG. 1 is a schematic view showing a display panel of the prior art. The display panel includes an active area 110 and a non-active area 120 surrounding the active area 110. The bonding area is located within the non-active area 120 and is located in the lower border of the display panel. The bonding area is provided with an IC 121 integrated with multiple circuit functions and a group of flexible printed circuit (FPC) terminals 122 for bonding with an FPC board. The FPC terminals 122 are located on the lower side of the IC 121 for bonding, resulting in a wide lower border.

FIG. 2 is a schematic view showing another display panel of the prior art. The bonding area of the display panel is provided with an IC 221 and two groups of bonding terminals 222 respectively on the left and right sides of the IC 221. In the actual production process, in order to improve the production yield of the display panel, the display panel is electrically tested through the electrical detection terminals 223 before bonding the flexible printed circuit board. The electrical detection terminals 223 needs to be electrically connected with the IC 221, but in the lower border of the display panel, there are two groups of bonding terminals 222 on the left and right sides of the IC 221, the electrical detection terminals 223 needs to be placed under the bonding area due to insufficient space. Therefore, it is necessary to use a longer glass substrate, and after the electrical detection is completed, it is necessary to cut off the electrical detection terminals 223 and part of the glass substrate along the cutting line 224, so as to achieve the purpose of narrowing the lower border. In this way, not only the manufacturing cost is increased, but also the production yield is affected by the secondary cutting.

### TECHNICAL SOLUTION

An object of the present invention is to provide a display panel with a narrow lower border and an electronic device with the display panel.

The present invention provides a display panel with a narrow lower border, including an active area and a non-active area surrounding the active area. The active area is provided with scanning lines and data lines which are intersected with each other. The non-active area includes a left border, a right border and a lower border. The lower border has a length direction extending from the left border to the right border. The lower border is provided with a first detection area, a first installation area, a bonding area, a second installation area and a second detection area which are arranged sequentially along the length direction. The first detection area is electrically connected with the first installation area. The second detection area is electrically connected with the second installation area. The bonding area is electrically connected with the first installation area and the second installation area. The bonding area is used to bond a flexible circuit board, the first installation area is used to install a first driving chip. The second installation area is used to install a second driving chip. The first detection area and the second detection area are used to transmit test signals to the display panel.

Further, the first detection area, the first installation area, the bonding area, the second installation area and the second detection area are arranged in a straight line along the length direction of the lower border.

Further, the left border is provided with a first gate driver circuit, the right border is provided with a second gate driver circuit. The first installation area includes a first gate terminal area, a first fan out terminal area and a first chip signal terminal area. The first gate terminal area is connected to the first gate driver circuit. The first fan out terminal area is connected to a part of the data lines in the active area through first fan out lines. The first chip signal terminal area is connected to the bonding area through first chip signal lead lines. The second installation area includes a second gate terminal area, a second fan out terminal area and a second chip signal terminal area. The second gate terminal area is connected to the second gate driver circuit. The second fan out terminal area is connected to another part of the data lines in the active area through second fan out lines. The second chip signal terminal area is connected to the bonding area through second chip signal lead lines.

Further, the first gate terminal area and the second gate terminal area are symmetrically arranged on both sides of the bonding area. The first fan out terminal area and the second fan out terminal area are symmetrically arranged on both sides of the bonding area. The first chip signal terminal area and the second chip signal terminal area are symmetrically arranged on both sides of the bonding area. The first driving chip and the second driving chip are symmetrically arranged on both sides of the bonding area.

Further, the display panel further includes a touch sensing terminal area spaced apart from the bonding area. The touch sensing terminal area is located on one side of the bonding area adjacent to the active area. The first installation area further includes a first chip touch terminal area. The first chip touch terminal area is connected to the bonding area through first chip touch lead lines. The second mounting area further includes a second chip touch terminal area. The second chip touch terminal area is connected to the bonding area through second chip touch lead lines.

Further, the first chip touch terminal area and the second chip touch terminal area are symmetrically arranged on both sides of the bonding area.

Further, the flexible circuit board is electrically connected to the bonding area and the touch sensing terminal area simultaneously by bonding.

Further, the first driving chip and the second driving chip are display/touch integrated driving chips. The first driving chip includes a first chip display circuit and a first chip touch circuit. The second driving chip includes a second chip display circuit and a second chip touch circuit. The first chip display circuit and the second chip display circuit are symmetrically arranged on both sides of the bonding area. The first chip touch circuit and the second chip touch circuit are symmetrically arranged on both sides of the bonding area. The first chip display circuit and the second chip display circuit are used to transmit display signals to the active area. The first chip touch circuit and the second chip touch circuit are used to receive and process touch sensing signals transmitted from the active area through the touch sensing terminal area.

Further, the bonding area is provided with a plurality of bonding terminals. The bonding terminals extend perpendicular to the length direction. Each bonding terminal has a first end adjacent to the active area and a second end far away from the active area. The first chip signal terminal area is connected to the second end of a part of the bonding terminals through the first chip signal lead lines. The second chip signal terminal area is connected to the second end of a part of the bonding terminals through the second chip signal lead lines. The first chip touch terminal area is connected to the first end of a part of the bonding terminals through the first chip touch lead lines. The second chip touch terminal area is connected to the first end of a part of the bonding terminals through the second chip touch lead lines.

Further, the bonding area is provided with a plurality of bonding terminals. The bonding terminals extend perpendicular to the length direction. Each bonding terminal has a first end adjacent to the active area and a second end far away from the active area. The first chip signal terminal area is connected to the first end of a part of the bonding terminals through the first chip signal lead lines. The second chip signal terminal area is connected to the first end of a part of the bonding terminals through the second chip signal lead lines. The first chip touch terminal area is connected to the first end of a part of the bonding terminals through the first chip touch lead lines. The second chip touch terminal area is connected to the first end of a part of the bonding terminals through the second chip touch lead lines.

The present invention further provides an electronic device including the display panel with a narrow lower border as described above.

### BENEFICIAL EFFECT

The display panel with a narrow lower border of the present invention sets the first installation area and the second installation area on both sides of the bonding area. The first driving chip is installed in the first installation area, and the second driving chip is installed in the second installation area. At the same time, the first detection area and the second detection area are respectively arranged outside the first installation area and the second installation area, so that the first detection area and the second detection area are directly electrically connected to the first driving chip and the second driving chip, respectively, so as to realize the electrical detection function of the display panel before bonding the flexible circuit board and before installing the first driving chip and the second driving chip. Since it is not necessary to set the first detection area and the second detection area under the bonding area, the lower border of the display panel can be narrowed, and no secondary processing is required to cut off the electrical detection terminals and part of the substrate, thereby reducing the cost and improving the production yield.

### BRIEF DESCRIPTION OF THE DRAWINGS

FIG. 1 is a schematic view showing a display panel of the prior art.

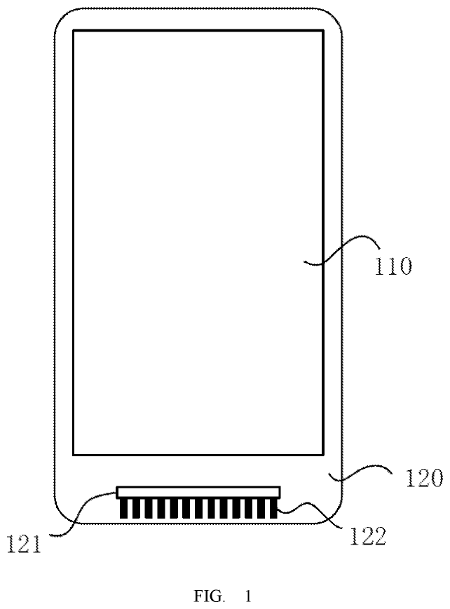

FIG. 2 is a schematic view showing another display panel of the prior art.

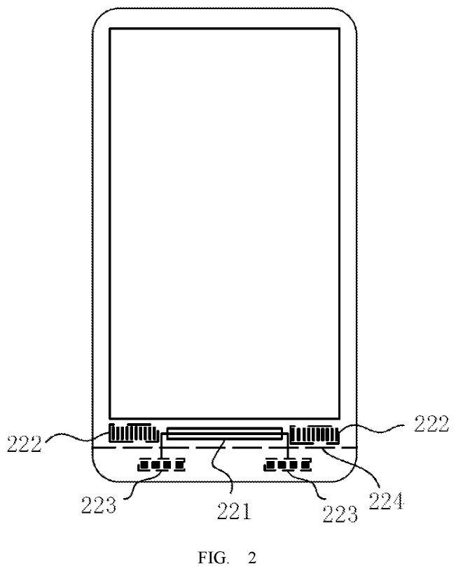

FIG. 3 is a schematic view of a display panel with a narrow lower border according to a first embodiment of the present invention.

FIG. 4 is a schematic view of the display panel shown in FIG. 3 after the first driving chip, the second driving chip and the flexible circuit board are installed.

FIG. 5 is a schematic view of the lower part of a display panel according to a second embodiment of the present invention.

FIG. 6 is a schematic view of the lower part of a display panel according to a third embodiment of the present invention.

FIG. 7 is a circuit connection diagram of the display panel shown in FIG. 6.

FIG. 8 is another circuit connection diagram of the display panel shown in FIG. 6.

FIG. 9 is a schematic view showing the structure of the first driving chip and the second driving chip in the display panel shown in FIG. 6.

### DETAILED DESCRIPTION OF PREFERRED EMBODIMENTS

The specific implementation of the present invention will be described in detail with reference to the accompanying drawings and embodiments. The following embodiments are used to illustrate the present invention, but not to limit the scope of the present invention.

### First Embodiment

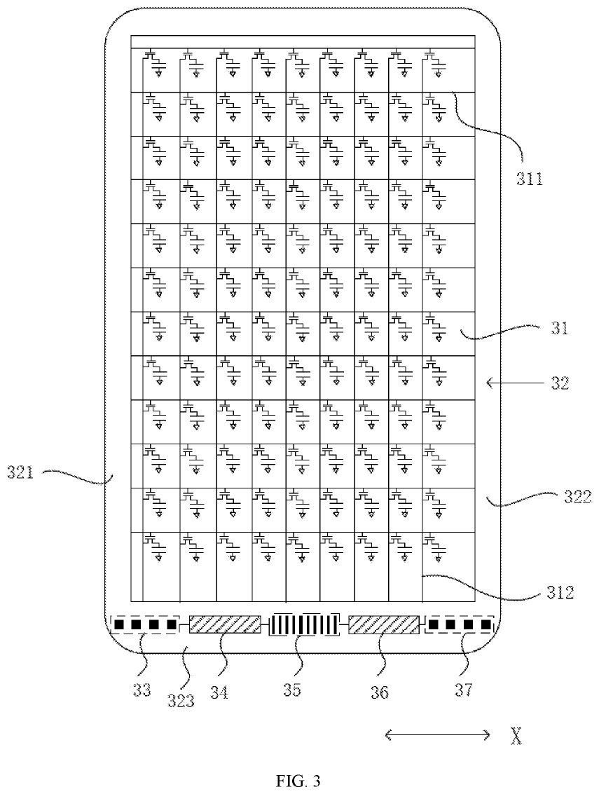

Referring to FIG. 3, it is a schematic view showing a display panel with a narrow lower border according to a first embodiment of the present invention. The display panel includes an active area 31 and a non-active area 32 surrounding the active area 31. The active area 31 is provided with a plurality of scanning lines 311 and a plurality of data lines 312 intersected with each other. The non-active area 32 includes a left border 321, a right border 322, and a lower border 323. The lower border 323 has a length direction X extending from the left border 321 to the right border 322. The lower border 323 is provided with a first detection area 33, a first installation area 34, a bonding area 35, a second installation area 36 and a second detection area 37 arranged sequentially along the length direction X.

In this embodiment, the first detection area 33, the first installation area 34, the bonding area 35, the second installation area 36 and the second detection area 37 are arranged in a straight line along the length direction X of the lower border 323. The bonding area 35 is located in the middle of the lower border 323, the first installation area 34 and the second installation area 36 are located on both sides of the bonding area 35, the first detection area 33 is located on the outside of the first installation area 34 (i.e., on the side of the first installation area 34 far away from the bonding area 35), and the second detection area 37 is located on the outside of the second installation area 36 (i.e., on the side of the second installation area 36 far away from the bonding area 35). Preferably, the first installation area 34 and the second installation area 36 are symmetrically arranged on both sides of the bonding area 35, and the first detection area 33 and the second detection area 37 are symmetrically arranged on both sides of the bonding area 35.

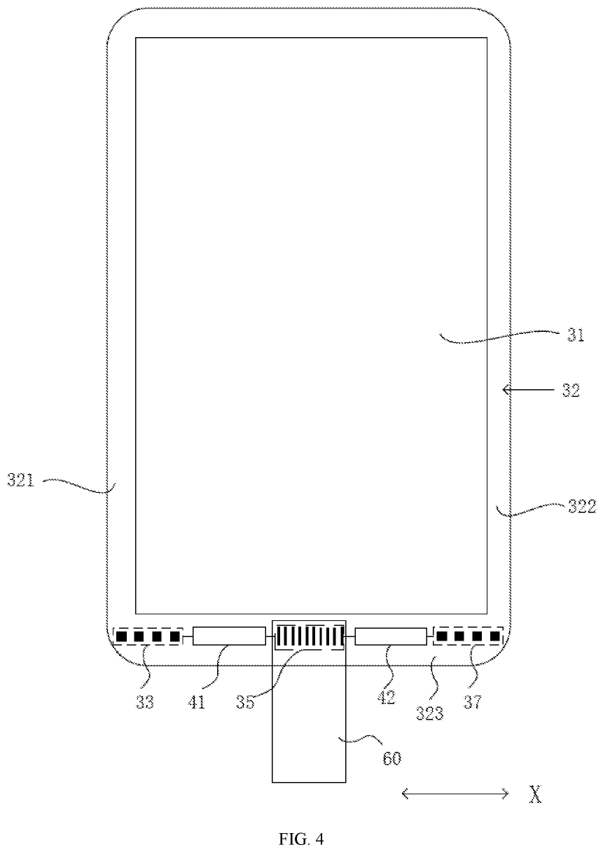

Referring to FIGS. 3 and 4, the first detection area 33 and the first installation area 34 are electrically connected. The second detection area 37 and the second installation area 36 are electrically connected. The bonding area 35 is used to bond a flexible circuit board 60. The first installation area 34 is used to install a first driving chip 41. The second installation area 36 is used to install a second driving chip 42. The first detection area 33 and the second detection area 37 are used to transmit test signals to the display panel. After the test signal transmission is completed, the flexible circuit board 60 is bonded to the bonding area 35, and the first driving chip 41 and the second driving chip 42 are respectively installed in the first installation area 34 and the second installation area 36. Specifically, during detection, the first detection area 33 transmits the test signals to the active area 31 through the first installation area 34, and the second detection area 37 transmits the test signals to the active area 31 through the second installation area 36, wherein the test signals include test data signals, clock signals, etc. After the detection, if the display panel can work normally, then the flexible circuit board 60 is bonded to the bonding area 35, the first driving chip 41 is installed to the first installation area 34, and the second driving chip 42 is installed to the second installation area 36, so that the unqualified display panel can be discarded in advance through the early detection process.

The first driving chip 41 is installed in the first installation area 34, the second driving chip 42 is installed in the second installation area 36. The first driving chip 41 and the second driving chip 42 are, for example, display/touch integrated driving chips. The first driving chip 41 and the second driving chip 42 are arranged symmetrically on both sides of the bonding area 35. Specifically, the first driving chip 41 includes a first chip circuit and a plurality of first chip terminals, wherein the plurality of first chip terminals are used to electrically connect the first chip circuit with the first installation area 34 during installation; the second driving chip 42 includes a second chip circuit and a plurality of second chip terminals, wherein the plurality of second chip terminals are used to electrically connect the second chip circuit with the second installation area 36 during installation. The first chip circuit and the second chip circuit are symmetric on both sides of the bonding area 35, and the plurality of first chip terminals and the plurality of second chip terminals are symmetric on both sides of the bonding area 35.

The flexible circuit board 60 is bonded to the bonding area 35, so that external signals can be transmitted to the display panel through the flexible circuit board 60 and the bonding area 35.

The display panel of this embodiment sets the first installation area 34 and the second installation area 36 on both sides of the bonding area 35, so that the function of the driving chip in the prior art can be divided into two parts, which are respectively arranged in the first driving chip 41 and the second driving chip 42 which are symmetrical with each other. The first driving chip 41 is installed in the first installation area 34, and the second driving chip 42 is installed in the second installation area 36. At the same time, the first detection area 33 and the second detection area 37 are respectively arranged outside the first installation area 34 and the second installation area 36, so that the first detection area 33 and the second detection area 37 are directly electrically connected to the first driving chip 41 and the second driving chip 42, respectively, so as to realize the electrical detection function of the display panel before bonding the flexible circuit board 60 and before installing the first driving chip 41 and the second driving chip 42. Since it is not necessary to set the first detection area 33 and the second detection area 37 under the bonding area 35, the lower border 323 of the display panel can be narrowed, and no secondary processing is required to cut off the electrical detection terminals and part of the substrate, thereby reducing the cost and improving the production yield.

### Second Embodiment

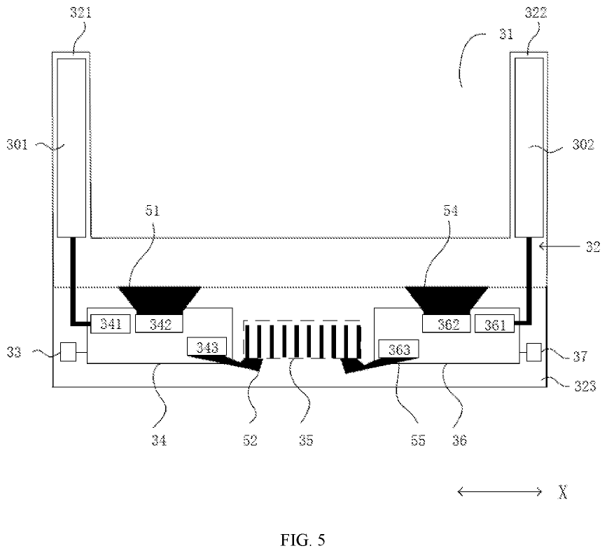

Referring to FIG. 5, it is a schematic view showing the lower part of the display panel according to a second embodiment of the present invention, and specifically illustrates a specific structure and setting of the terminals of the first installation area 34 and the second installation area 36.

Referring to FIG. 3 and FIG. 5, the display panel of this embodiment adopts an embedded gate on array (GOA), that is, a first gate driver circuit 301 is set on the left border 321, and a second gate driver circuit 302 is set on the right border 322. The first gate driver circuit 301 and the second gate driver circuit 302 are used to drive the scanning lines 311 in the active area 31.

The first installation area 34 includes a first gate terminal area 341, a first fan out terminal area 342 and a first chip signal terminal area 343. The first gate terminal area 341 is connected to the first gate driver circuit 301. The first fan out terminal area 342 is connected to a part of the data lines 312 in the active area 31 through the first fan out lines 51. The first chip signal terminal area 343 is connected to the bonding area 35 through the first chip signal lead lines 52.

The second installation area 36 includes a second gate terminal area 361, a second fan out terminal area 362 and a second chip signal terminal area 363. The second gate terminal area 361 is connected to the second gate driver circuit 302. The second fan out terminal area 362 is connected to another part of the data lines 312 in the active area 31 through the second fan out lines 54. The second chip signal terminal area 363 is connected to the bonding area 35 through the second chip signal lead lines 55.

Further, the number of the data lines 312 connecting the first fan out terminal area 342 and the other part of the data lines 312 connecting the second fan out terminal area 362 are equally distributed, and the positions thereof are symmetrically distributed with respect to the bonding area 35.

The first driving chip 41 transmits the clock signal (CLK), start signal (STV), reset signal (RESET) and other signals to the first gate driver circuit 301 through the first gate terminal area 341 in order to drive a part of the scanning lines 311 in the active area 31. The first driving chip 41 transmits data signals to a part of the data lines 312 in the active area 31 through the first fan out terminal area 342 and the first fan out lines 51 in order to drive a part of the data lines 312 in the active area 31. The first driving chip 41 is electrically connected with the bonded flexible circuit board 60 through the first chip signal terminal area 343 and the first chip signal lead lines 52 to receive the IC power and other signals transmitted by the flexible circuit board 60.

The second driving chip 42 transmits the clock signal (CLK), start signal (STV), reset signal (RESET) and other signals to the second gate driver circuit 302 through the second gate terminal area 361 in order to drive another part of the scanning lines 311 in the active area 31. The second driving chip 42 transmits data signals to another part of the data lines 312 in the active area 31 through the second fan out terminal area 362 and the second fan out lines 54 in order to drive another part of the data lines 312 in the active area 31. The second driving chip 42 is electrically connected with the bonded flexible circuit board 60 through the second chip signal terminal area 363 and the second chip signal lead lines 55 to receive the IC power and other signals transmitted by the flexible circuit board 60.

A plurality of first chip terminals of the first driving chip 41 are electrically connected with a plurality of terminals of the first gate terminal area 341, the first fan out terminal area 342 and the first chip signal terminal area 343 during installation. A plurality of second chip terminals of the second driving chip 42 are electrically connected with a plurality of terminals of the second gate terminal area 361, the second fan out terminal area 362 and the second chip signal terminal area 363.

In this embodiment, specifically, the first gate terminal area 341 and the second gate terminal area 361 are symmetrically arranged on both sides of the bonding area 35, the first fan out terminal area 342 and the second fan out terminal area 362 are symmetrically arranged on both sides of the bonding area 35, and the first chip signal terminal area 343 and the second chip signal terminal area 363 are symmetrically arranged on both sides of the bonding area 35.

### Third Embodiment

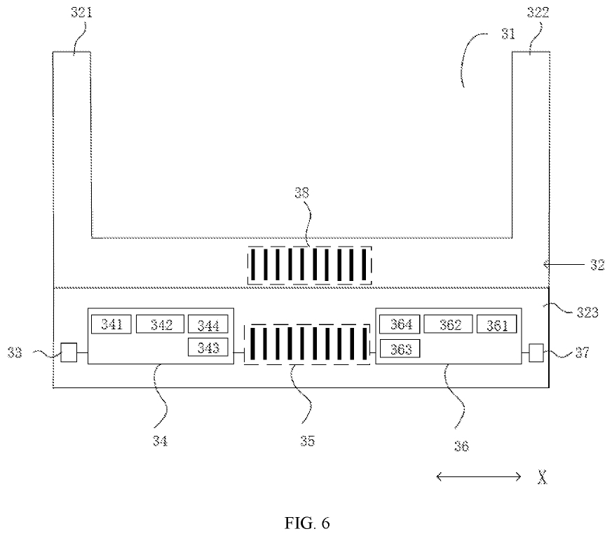

Referring to FIG. 6, it is a schematic view showing the lower part of the display panel according to a third embodiment of the present invention. The display panel of this embodiment is a touch display panel, and the display panel further includes a touch sensing terminal area 38 arranged at intervals with the bonding area 35. The touch sensing terminal area 38 can be located on one side of the bonding area 35 adjacent to the active area 31.

Specifically, the display panel of this embodiment can be a liquid crystal display panel, including an array substrate, a color filter substrate and a liquid crystal layer sandwiched between the array substrate and the color filter substrate. The array substrate and the color filter substrate are bonded through a plastic frame located in the non-active area 32. The first detection area 33, the first installation area 34, the bonding area 35, the second installation area 36 and the second detection area 37 are arranged at the lower border of the array substrate, while the touch sensing terminal area 38 is arranged at the lower border of the color filter substrate, wherein the size of the lower border of the array substrate is larger than the size of the lower border of the color filter substrate, so that after the color filter substrate and the array substrate are assembled, the lower border of the array substrate is exposed, so as to facilitate bonding the flexible circuit board 60 and installing the first driving chip 41 and the second driving chip 42.

The color filter substrate includes a black matrix, a color filter layer and a touch sensing layer for sensing touch positions. The touch sensing layer can transmit the touch sensing signals to the first driving chip 41 and the second driving chip 42 through the touch sensing terminal area 38.

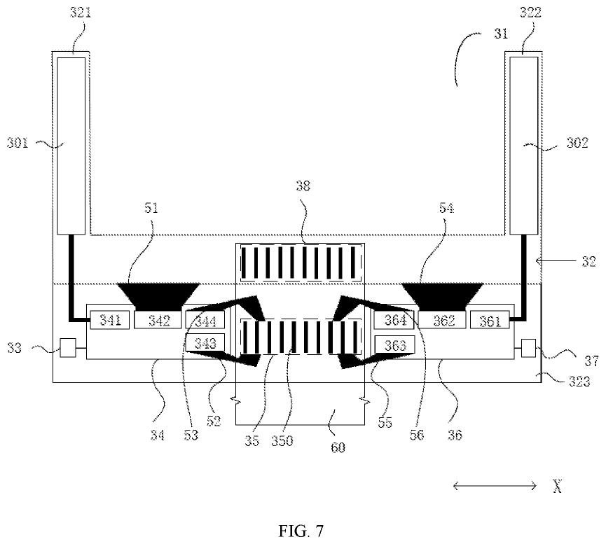

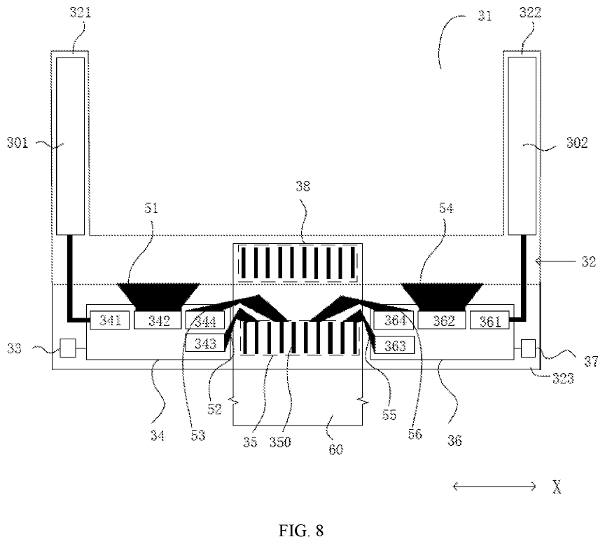

Referring to FIG. 7 and FIG. 8, in this embodiment, the first installation area 34 further includes a first chip touch terminal area 344, and the first chip touch terminal area 344 is connected to the bonding area 35 through the first chip touch lead lines 53. The second installation area 36 further includes a second chip touch terminal area 364, and the second chip touch terminal area 364 is connected to the bonding area 35 through the second chip touch lead lines 56. Preferably, the first chip touch terminal area 344 and the second chip touch terminal area 364 are symmetrically arranged on both sides of the bonding area 35.

The flexible circuit board 60 is electrically connected to the bonding area 35 and the touch sensing terminal area 38 by bonding. The bonding area 35 and the touch sensing terminal area 38 are separated from each other. Preferably, the touch sensing terminal area 38 can be located above the bonding area 35, so that the flexible circuit board 60 can be bonded with the touch sensing terminal area 38 and the bonding area 35 simultaneously in a narrow range.

It should be noted that the touch display panel of the present invention is not limited to a liquid crystal display panel. In OLED, micro-LED and other types of display panels, the bonding area 35 and the touch sensing terminal area 38 can also be provided to realize the flexible circuit board 60 bonding with the both simultaneously, so as to realize the touch function of the narrow border display panel.

Referring to FIG. 7 and FIG. 8, a plurality of bonding terminals 350 are provided in the bonding area 35. The bonding terminals 350 extend perpendicular to the length direction X of the lower border 323, and each bonding terminal 350 has a first end adjacent to the active area 31 and a second end far away from the active area 31.

In FIG. 7, the first chip signal terminal area 343 is connected to the second end of a part of the bonding terminals 350 through the first chip signal lead lines 52. The second chip signal terminal area 363 is connected to the second end of a part of the bonding terminals 350 through the second chip signal lead lines 55. The first chip touch terminal area 344 is connected to the first end of a part of the bonding terminals 350 through the first chip touch lead lines 53. The second chip touch terminal area 364 is connected to the first end of a part of the bonding terminals 350 through the second chip touch lead lines 56.

In FIG. 8, the first chip signal terminal area 343 is connected to the first end of a part of the bonding terminals 350 through the first chip signal lead lines 52. The second chip signal terminal area 363 is connected to the first end of a part of the bonding terminals 350 through the second chip signal lead lines 55. The first chip touch terminal area 344 is connected to the first end of a part of the bonding terminals 350 through the first chip touch lead lines 53. The second chip touch terminal area 364 is connected to the first end of a part of the bonding terminals 350 through the second chip touch lead lines 56.

In FIG. 8, the first chip signal lead lines 52, the second chip signal lead lines 55, the first chip touch lead lines 53 and the second chip touch lead lines 56 are all connected to the same end (i.e., the first end) of the bonding terminals 350, so as to reduce the number of lead lines under the bonding area 35 and further narrow the lower border 323 of the display panel.

A plurality of first chip terminals of the first driving chip 41 are also electrically connected with a plurality of terminals of the first chip touch terminal area 344 during installation. A plurality of second chip terminals of the second driving chip 42 are also electrically connected with a plurality of terminals of the second chip touch terminal area 364 during installation.

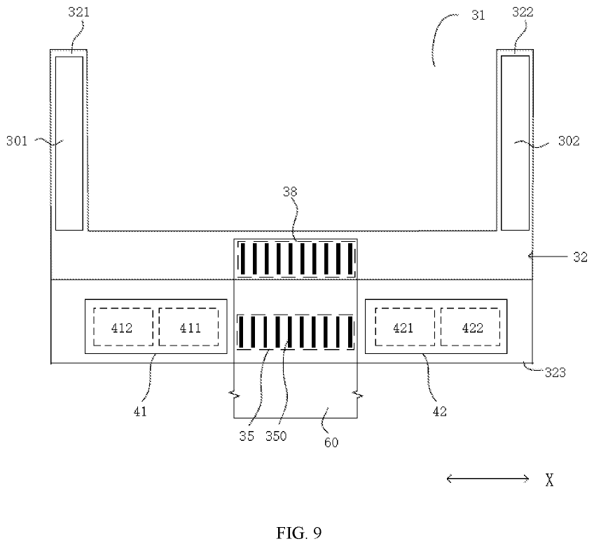

In this embodiment, both the first driving chip 41 and the second driving chip 42 are display/touch integrated driving chips. Specifically, please refer to FIG. 9, the first driving chip 41 includes a first chip display circuit 411 and a first chip touch circuit 412, and the second driving chip 42 includes a second chip display circuit 421 and a second chip touch circuit 422. The first chip display circuit 411 and the second chip display circuit 421 are symmetrically arranged on both sides of the bonding area 35. The first chip touch circuit 412 and the second chip touch circuit 422 are symmetrically arranged on both sides of the bonding area 35. It should be noted that FIG. 9 is only the schematic diagram of the first driving chip 41 and the second driving chip 42. The circuits of the first chip display circuit 411 and the first chip touch circuit 412 in the first driving chip 41 may be integrated with each other and share some common electronic components. The circuits of the second chip display circuit 421 and the second chip touch circuit 422 in the second driving chip 42 may be integrated with each other and share some common electronic components.

The first chip display circuit 411 and the second chip display circuit 421 are used to transmit display signals to the active area 31. The display signals include scanning signals, data signals, etc. The first chip display circuit 411 and the second chip display circuit 421 are not only symmetrical in circuits, but also transmit signals to the symmetrical signal lines in the active area 31. The first chip touch circuit 412 and the second chip touch circuit 422 are used to receive and process the touch sensing signals transmitted from the active area 31 through the touch sensing terminal area 38. The touch sensing signals are detected by the touch sensing layer on the color filter substrate. The first chip touch circuit 412 and the second chip touch circuit 422 are not only symmetrical in circuits, but also receive and process the touch sensing signals detected by the symmetric touch sensing layer on the color filter substrate. For example, the first chip touch circuit 412 is used to receive and process the touch sensing signals detected by the left half of the touch sensing layer on the color filter substrate, and the second chip touch circuit 422 is used to receive and process the touch sensing signals detected by the right half of the touch sensing layer on the color filter substrate. For another example, the touch sensing layer includes a plurality of first touch sensing regions and a plurality of second touch sensing regions, the plurality of first touch sensing regions and the plurality of second touch sensing regions are symmetric, the first chip touch circuit 412 is used to receive and process the touch sensing signals detected by the first touch sensing regions, and the second chip touch circuit 422 is used to receive and process the second touch sensing signals detected by the second touch sensing regions.

In the touch display panel of the embodiments, the first detection area 33, the first installation area 34, the bonding area 35, the second installation area 36 and the second detection area 37 are arranged in sequence, the flexible circuit board 60 are bonded to the touch sensing terminal area 38 and the bonding area 35 at the same time, and two symmetrical display/touch integrated driving chips are used to realize the touch function of the narrow border display panel.

Further, the present invention also provides an electronic device, which includes a display panel with a narrow lower border as described above. Specifically, the electronic device may be a mobile phone, a tablet computer, a digital camera, etc.

The above is only the specific embodiments of the present invention, but the protection scope of the invention is not limited to this. Any technical person in the art can easily think of changes or replacements within the technical principle disclosed by the invention, which shall be included within the protection scope of the invention. Therefore, the protection scope of the invention shall be subject to the claims.

1. A display panel with a narrow lower border comprising an active area and a non-active area surrounding the active area, the active area being provided with scanning lines and data lines which are intersected with each other, the non-active area comprising a left border, a right border and a lower border, the lower border having a length direction extending from the left border to the right border,
wherein the lower border is provided with a first detection area, a first installation area, a bonding area , a second installation area and a second detection area which are arranged sequentially along the length direction, the first detection area is electrically connected with the first installation area, the second detection area is electrically connected with the second installation area, the bonding area is electrically connected with the first installation area and the second installation area,
the bonding area is used to bond a flexible circuit board, the first installation area is used to install a first driving chip, the second installation area is used to install a second driving chip, the first detection area and the second detection area are used to transmit test signals to the display panel.

2. The display panel with a narrow lower border according to claim 1, wherein the first detection area, the first installation area, the bonding area, the second installation area and the second detection area are arranged in a straight line along the length direction of the lower border.

3. The display panel with a narrow lower border according to claim 1, wherein the left border is provided with a first gate driver circuit, the right border is provided with a second gate driver circuit;
the first installation area includes a first gate terminal area, a first fan out terminal area and a first chip signal terminal area, the first gate terminal area is connected to the first gate driver circuit, the first fan out terminal area is connected to a part of the data lines in the active area through first fan out lines, the first chip signal terminal area is connected to the bonding area through first chip signal lead lines;
the second installation area includes a second gate terminal area, a second fan out terminal area and a second chip signal terminal area, the second gate terminal area is connected to the second gate driver circuit, the second fan out terminal area is connected to another part of the data lines in the active area through second fan out lines, the second chip signal terminal area is connected to the bonding area through second chip signal lead lines.

4. The display panel with a narrow lower border according to claim 3, wherein the first gate terminal area and the second gate terminal area are symmetrically arranged on both sides of the bonding area, the first fan out terminal area and the second fan out terminal area are symmetrically arranged on both sides of the bonding area, the first chip signal terminal area and the second chip signal terminal area are symmetrically arranged on both sides of the bonding area, the first driving chip and the second driving chip are symmetrically arranged on both sides of the bonding area.

5. The display panel with a narrow lower border according to claim 3, wherein the display panel further includes a touch sensing terminal area spaced apart from the bonding area, the touch sensing terminal area is located on one side of the bonding area adjacent to the active area;
the first installation area further includes a first chip touch terminal area, the first chip touch terminal area is connected to the bonding area through first chip touch lead lines;
the second mounting area further includes a second chip touch terminal area, the second chip touch terminal area is connected to the bonding area through second chip touch lead lines.

6. The display panel with a narrow lower border according to claim 5, wherein the first chip touch terminal area and the second chip touch terminal area are symmetrically arranged on both sides of the bonding area.

7. The display panel with a narrow lower border according to claim 5, wherein the flexible circuit board is electrically connected to the bonding area and the touch sensing terminal area simultaneously by bonding.

8. The display panel with a narrow lower border according to claim 5, wherein the first driving chip and the second driving chip are display/touch integrated driving chips, the first driving chip includes a first chip display circuit and a first chip touch circuit, the second driving chip includes a second chip display circuit and a second chip touch circuit;
the first chip display circuit and the second chip display circuit are symmetrically arranged on both sides of the bonding area, the first chip touch circuit and the second chip touch circuit are symmetrically arranged on both sides of the bonding area;
the first chip display circuit and the second chip display circuit are used to transmit display signals to the active area, the first chip touch circuit and the second chip touch circuit are used to receive and process touch sensing signals transmitted from the active area through the touch sensing terminal area.

9. The display panel with a narrow lower border according to claim 5, wherein the bonding area is provided with a plurality of bonding terminals, the bonding terminals extend perpendicular to the length direction, each bonding terminal has a first end adjacent to the active area and a second end far away from the active area;
the first chip signal terminal area is connected to the second end of a part of the bonding terminals through the first chip signal lead lines, the second chip signal terminal area is connected to the second end of a part of the bonding terminals through the second chip signal lead lines;
the first chip touch terminal area is connected to the first end of a part of the bonding terminals through the first chip touch lead lines, the second chip touch terminal area is connected to the first end of a part of the bonding terminals through the second chip touch lead lines.

10. The display panel with a narrow lower border according to claim 5, wherein the bonding area is provided with a plurality of bonding terminals, the bonding terminals extend perpendicular to the length direction, each bonding terminal has a first end adjacent to the active area and a second end far away from the active area;
the first chip signal terminal area is connected to the first end of a part of the bonding terminals through the first chip signal lead lines, the second chip signal terminal area is connected to the first end of a part of the bonding terminals through the second chip signal lead lines;
the first chip touch terminal area is connected to the first end of a part of the bonding terminals through the first chip touch lead lines, the second chip touch terminal area is connected to the first end of a part of the bonding terminals through the second chip touch lead lines.

11. An electronic device comprising a display panel with a narrow lower border according to claim 1.
